(19) United States
(12) Patent Application Publication
(10) Pub. No.: US 2026/0282221 A1
(43) Pub. Date: Sep. 17, 2026

(54) RESIN COMPOSITION, PREPREG, LAYERED SHEET, PRINTED CIRCUIT BOARD, AND SEMICONDUCTOR PACKAGE

(71) Applicant: Resonac Corporation, Minato-ku, Tokyo (JP)

(72) Inventors: Shiori MATSUOKA, Minato-ku, Tokyo (JP); Fumitaka UENO, Minato-ku, Tokyo (JP); Yoshiki HIDAKA, Minato-ku, Tokyo (JP); Yuta NAKANO, Minato-ku, Tokyo (JP); Kohta IWANAGA, Minato-ku, Tokyo (JP); Shota NAKAMURA, Minato-ku, Tokyo (JP)

(21) Appl. No.: 19/167,760

(22) PCT Filed: Sep. 25, 2024
(86) PCT No.: PCT/JP2024/034027

§ 371 Date: Sep. 22, 2025

(30) Foreign Application Priority Data
Oct. 2, 2023 (JP) 2023-171389

(51) Int. Cl. H05K 1/03; C08K 3/013; C08K 3/36

(52) U.S. Cl. CPC H05K 1/0373; C08K 3/013; C08K 3/36; H05K 2201/0209; H05K 2201/0355

(57) ABSTRACT

Provided are a resin composition containing: (A) a thermosetting resin, (B) an inorganic filler having a true density of 1,500 kg/m³ or less, and (C) an inorganic filler having a true density of more than 1,500 kg/m³, a prepreg, a layered sheet, a resin film, a printed circuit board, and a semiconductor package in which the resin composition is used.

### TECHNICAL FIELD

The present embodiment relates to a resin composition, a prepreg, a layered sheet, a printed circuit board, and a semiconductor package.

### BACKGROUND ART

In electronic devices such as a mobile communication device represented by a mobile phone, a base station device thereof, a network infrastructure device such as a server or a router, or a large computer, the speed and the capacity of a signal to be used are increasing year by year. Accordingly, dielectric characteristics capable of reducing a transmission loss of a high-frequency signal (hereinafter, sometimes referred to as “high-frequency characteristics”), that is, a reduction in relative permittivity is required for a substrate material of a printed circuit board to be mounted on these electronic devices.

For example, PTL 1 discloses, as a substrate material that may achieve a low transmission loss, a resin composition containing: (A) one or more selected from the group consisting of a maleimide compound having at least two N-substituted maleimide groups and a derivative thereof, (B) one or more selected from the group consisting of polyphenylene ether and a derivative thereof, and (C) a copolymer having a structural unit derived from a styrene-based compound, a structural unit derived from maleic anhydride, and a structural unit derived from N-substituted maleimide.

### CITATION LIST

### Patent Literature

PTL 1: JP 2020-169276 A

### SUMMARY OF INVENTION

### Technical Problem

The technology of PTL 1 can exhibit excellent dielectric characteristics in a high-frequency band of 10 GHz or more. However, in recent years, requirement for a reduction in relative permittivity is increasing, and the technology for achieving the reduction is required.

According to a build-up production technology, a via hole for interlayer connection may be formed by a laser method in a metal-clad layered sheet that is a laminate including an insulating layer and a metal foil. However, from the investigation by the inventors of the present invention, it is found that when a via hole is formed by a laser method in a metal-clad layered sheet formed from a resin composition having a reduced relative permittivity, the metal foil around the via hole may be bulged or peeled.

Accordingly, both a satisfactory relative permittivity (Dk) and suppression of bulge or peeling of the metal foil at the time of laser processing (hereinafter also referred to as “laser processability”) are required.

In view of such a current situation, an object of the present embodiment is to provide a resin composition having excellent relative permittivity (Dk) and laser processability, a prepreg, a layered sheet, a resin film, a printed circuit board, and a semiconductor package in which the resin composition is used.

### Solution to Problem

Specifically, the present embodiment provides the following [1] to [12].
[1]A resin composition containing: (A) a thermosetting resin; (B) an inorganic filler having a true density of 1,500 kg/m³ or less; and (C) an inorganic filler having a true density of more than 1,500 kg/m³.
[2] The resin composition according to [1], wherein the component (B) is a particle having a siloxane bond.
[3] The resin composition according to [1] or [2], wherein a content of the component (B) is 1 to 30 mass % with respect to the total amount (100 mass %) of a solid content of the resin composition.
[4] The resin composition according to any one of [1] to [3], wherein the component (C) is silica.
[5] The resin composition according to any one of [1] to [4], wherein a content of the component (C) is 2 to 40 mass % with respect to the total amount (100 mass %) of the solid content of the resin composition.
[6] The resin composition according to any one of [1] to [5], wherein a difference between a true density of the component (B) and a true density of the component (C) [true density of component (C)−true density of component (B)] is 400 to 1,000 kg/m³.
[7] The resin composition according to any one of [1] to [6], wherein the component (A) is one or more selected from the group consisting of a maleimide compound having one or more N-substituted maleimide groups and a derivative of the maleimide resin.
[8]A prepreg containing: the resin composition according to any one of [1] to [7] or a semi-cured product of the resin composition.
[9]A layered sheet including: a cured product of the resin composition according to any one of [1] to [7]; and a metal foil.
[10]A resin film containing: the resin composition according to any one of [1] to [7] or a semi-cured product of the resin composition.
[11]A printed circuit board including: a cured product of the resin composition according to any one of [1] to [7].
[12]A semiconductor package including: the printed circuit board according to [11]; and a semiconductor element.

### Advantageous Effects of Invention

According to the present embodiment, it is possible to provide a resin composition having excellent relative permittivity (Dk) and laser processability, a prepreg, a layered sheet, a resin film, a printed circuit board, and a semiconductor package in which the resin composition is used.

### DESCRIPTION OF EMBODIMENTS

In the present description, a numerical range indicated by using “to” indicates a range including numerical values described before and after “to” as a minimum value and a maximum value, respectively.

For example, the expression of the numerical value range of “X to Y” (X and Y are real numbers) means the numerical value range of X or more and Y or less. Further, the expression of “X or more” in the present description means X and a numerical value exceeding X. Furthermore, the expression of “Y or less” in the present description means Y and a numerical value less than Y.

The lower limit value and the upper limit value of a numerical range described in the present description can be optionally combined with the lower limit value or the upper limit value of another numerical range, respectively.

In a numerical range described in the present description, the lower limit value or the upper limit value of the numerical range may be replaced with a value shown in Examples.

Each component and material exemplified in the present description may be used alone or two or more kinds thereof may be used in combination, unless particularly otherwise specified.

In the present description, when a plurality of substances corresponding to components are present in a resin composition, the content of each of the components in the resin composition means the total amount of the plurality of substances present in the resin composition, unless particularly otherwise specified.

In the present description, the “solid” means a component other than a solvent, and a component in a liquid state at 25° C. is also regarded as the solid.

The number-average molecular weight (Mn) in the present description means a value measured in terms of polystyrene by gel permeation chromatography (GPC). Specifically, the number-average molecular weight (Mn) in the present description can measured by a method described in Examples.

The “semi-cured product” in the present description is synonymous with the resin composition in the B-stage state in JIS K6800 (2006), and the “cured product” is synonymous with the resin composition in the C-stage state in JIS-K6800 (2006).

The mechanism of action described in the present description is a conjecture, and does not limit the mechanism of achieving the effect of the present embodiment.

Aspects in which the matters described in the present description are optionally combined are also included in the present embodiment.

### [Resin Composition]

A resin composition of the present embodiment is a resin composition containing: (A) a thermosetting resin; (B) an inorganic filler having a true density of 1,500 kg/m³ or less; and (C) an inorganic filler having a true density of more than 1,500 kg/m³.

In the present description, each component may be sometimes referred to as an abbreviation such as the component (A), the component (B), and the like, which will be true for the other components as well in some cases.

Although the reason for excellent relative permittivity (Dk) and laser processability of the resin composition of the present embodiment is not clear, the reason is presumed as follows.

The component (B) contained in the resin composition of the present embodiment has a true density of 1,500 kg/m³ or less, and hence the component (B) has a large volume of space at the molecular level. This is presumed to be one cause of a reduction in relative permittivity (Dk). Meanwhile, although the detailed cause is not clear, at the time of forming a via hole by a laser method, a metal foil around the via hole is easily bulged or peeled in a metal-clad layered sheet including a cured product of the resin composition containing the component (B) as an insulating layer. The resin composition of the present embodiment further contains the inorganic filler having a true density of more than 1,500 kg/m³ as the component (C) and the component (C) is located near the component (B) that tends to be damaged due to laser irradiation. Accordingly, it is presumed that the vicinity of the component (B) tends to be less damaged due to laser irradiation.

The components that may be contained in the resin composition of the present embodiment will be described below in turn.

### <(A) Thermosetting Resin>

Examples of the thermosetting resin (A) include an epoxy resin, a phenol resin, a maleimide resin, a cyanate resin, an isocyanate resin, a benzoxazine resin, an oxetane resin, an amino resin, an unsaturated polyester resin, an allyl resin, a dicyclopentadiene resin, a silicone resin, a triazine resin, and a melamine resin. Of these, from the viewpoint of heat resistance and adhesion to conductors, as the thermosetting resin (A), one or more selected from the group consisting of an epoxy resin, a cyanate resin, and a maleimide resin are preferred, a maleimide resin is more preferred, and one or more selected from the group consisting of a maleimide resin having one or more N-substituted maleimide groups and a derivative of the maleimide resin (hereinafter also referred to as “maleimide-based resin”) are still more preferred.

The thermosetting resin (A) may be used alone, or two or more kinds thereof may be used in combination.

In the following description, the maleimide resin having one or more N-substituted maleimide groups may be referred to as a “maleimide resin (AX)” or a “component (AX).” In addition, a derivative of the maleimide resin having one or more N-substituted maleimide groups may be referred to as a “maleimide resin derivative (AY)” or a “component (AY).”

### (Maleimide Resin (AX))

The maleimide resin (AX) is not particularly limited as long as it is a maleimide resin having one or more N-substituted maleimide groups.

From the viewpoint of adhesion to conductors and heat resistance, the maleimide resin (AX) is preferably an aromatic maleimide resin having two or more N-substituted maleimide groups, and more preferably an aromatic bismaleimide resin having two N-substituted maleimide groups.

In the present description, the “aromatic maleimide resin” means a compound having an N-substituted maleimide group directly bonded to an aromatic ring. Further, in the present description, the “aromatic bismaleimide resin” means a compound having two N-substituted maleimide groups directly bonded to an aromatic ring. Furthermore, in the present description, the “aromatic polymaleimide resin” means a compound having three or more N-substituted maleimide groups directly bonded to an aromatic ring. In addition, in the present description, the “aliphatic maleimide resin” means a compound having an N-substituted maleimide group directly bonded to an aliphatic hydrocarbon.

The maleimide resin (AX) is preferably a maleimide resin represented by the following general formula (A-1).

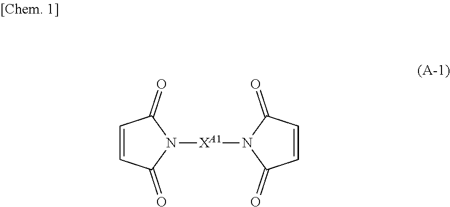

In the formula, X^{A1} is a divalent organic group.

X^{A1} in the general formula (A-1) is a divalent organic group.

Examples of the divalent organic group represented by X^{A1} in the general formula (A-1) include a divalent organic group represented by the following general formula (A-2), a divalent organic group represented by the following general formula (A-3), a divalent organic group represented by the following general formula (A-4), a divalent organic group represented by the following general formula (A-5), a divalent organic group represented by the following general formula (A-6), and a divalent organic group represented by the following general formula (A-7).

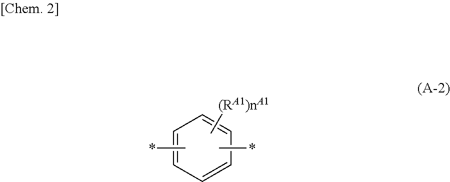

In the formula, R^{A1} is an aliphatic hydrocarbon group having 1 to 5 carbon atoms or a halogen atom; n^{A1} is an integer of 0 to 4; and * represents a bonding site.

Examples of the aliphatic hydrocarbon group having 1 to 5 carbon atoms represented by R^{A1} in the general formula (A-2) include alkyl groups having 1 to 5 carbon atoms such as a methyl group, an ethyl group, a n-propyl group, an isopropyl group, a n-butyl group, an isobutyl group, a t-butyl group, and a n-pentyl group; alkenyl groups having 2 to 5 carbon atoms; and alkynyl groups having 2 to 5 carbon atoms. The aliphatic hydrocarbon group having 1 to 5 carbon atoms may be either linear or branched.

Examples of the halogen atom include a fluorine atom, a chlorine atom, a bromine atom, and an iodine atom.

In the general formula (A-2), n^{A1} is an integer of 0 to 4, and from the viewpoint of ease of availability, it is preferably an integer of 0 to 2, more preferably 0 or 1, and still more preferably 0. When n^{A1} is an integer of 2 or more, a plurality of R^{A1}'s may be the same as or different from each other.

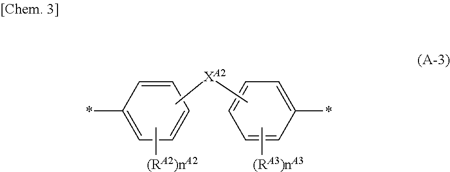

In the formula, R^{A2} and R^{A3} are each independently an aliphatic hydrocarbon group having 1 to 5 carbon atoms or a halogen atom; X^{A2} is an alkylene group having 1 to 5 carbon atoms, an alkylidene group having 2 to 5 carbon atoms, an ether group, a sulfide group, a sulfonyl group, a carbonyloxy group, a keto group, a single bond, or a divalent organic group represented by the following general formula (A-3-1); n^{A2} and n^{A3} are each independently an integer of 0 to 4; and * represents a bonding site.

Examples of the aliphatic hydrocarbon group having 1 to 5 carbon atoms and the halogen atom represented by R^{A2} and R^{A3} in the general formula (A-3) are the same as the examples of the aliphatic hydrocarbon group having 1 to 5 carbon atoms and the halogen atom represented by R^{A1}.

Examples of the alkylene group having 1 to 5 carbon atoms represented by X^{A2} in the general formula (A-3) include a methylene group, a 1,2-dimethylene group, a 1,3-trimethylene group, a 1,4-tetramethylene group, and a 1,5-pentamethylene group. The alkylene group having 1 to 5 carbon atoms is preferably an alkylene group having 1 to 3 carbon atoms, more preferably an alkylene group having 1 or 2 carbon atoms, and still more preferably a methylene group.

Examples of the alkylidene group having 2 to 5 carbon atoms represented by X^{A2} in the general formula (A-3) include an ethylidene group, a propylidene group, an isopropylidene group, a butylidene group, an isobutylidene group, a pentylidene group, and an isopentylidene group.

n^{A2} and n^{A3} in the general formula (A-3) are each independently an integer of 0 to 4.

When n^{A2} or n^{A3} is an integer of 2 or more, a plurality of R^{A2}'s or a plurality of R^{A3}'s may be the same as or different from each other.

The divalent organic group represented by the general formula (A-3-1) represented by X^{A2} in the general formula (A-3) is as follows.

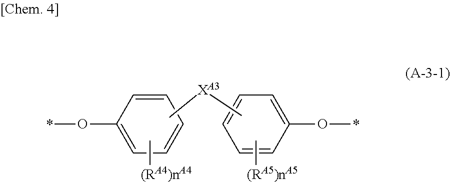

In the formula, R^{A4} and R^{A5} are each independently an aliphatic hydrocarbon group having 1 to 5 carbon atoms or a halogen atom; X^{A3} is an alkylene group having 1 to 5 carbon atoms, an alkylidene group having 2 to 5 carbon atoms, an ether group, a sulfide group, a sulfonyl group, a carbonyloxy group, a keto group, or a single bond; n^{A4} and n^{A5} are each independently an integer of 0 to 4; and * represents a bonding site.

Examples of the aliphatic hydrocarbon group having 1 to 5 carbon atoms and the halogen atom represented by R^{A4} and R^{A5} in the general formula (A-3-1) are the same as the examples of the aliphatic hydrocarbon group having 1 to 5 carbon atoms and the halogen atom represented by R^{A1}.

Examples of the alkylene group having 1 to 5 carbon atoms and the alkylidene group having 2 to 5 carbon atoms represented by X^{A3} in the general formula (A-3-1) are the same as the examples of the alkylene group having 1 to 5 carbon atoms and the alkylidene group having 2 to 5 carbon atoms represented by X^{A2}.

n^{A4} and n^{A5} in the general formula (A-3-1) are each independently an integer of 0 to 4, and from the viewpoint of easy availability, both of them are preferably an integer of 0 to 2, more preferably 0 or 1, and still more preferably 0.

When n^{A4} or n^{A5} is an integer of 2 or more, a plurality of R^{A4}'s or a plurality of R^{A5}'s may be the same as or different from each other.

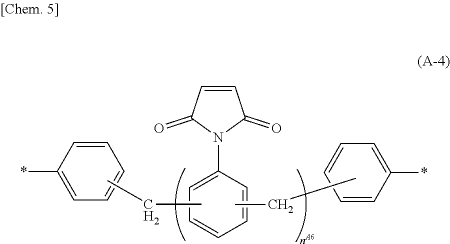

In the formula, n^{A6} is an integer of 0 to 10; and * represents a bonding site.

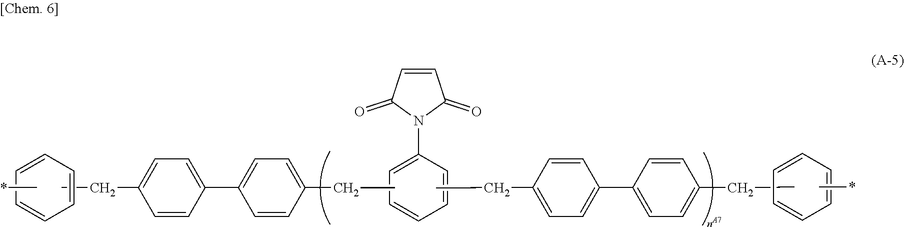

In the formula, n^{A7} is a number of 0 to 5; and * represents a bonding site.

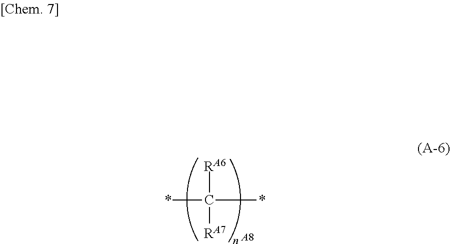

In the formula, R^{A6} and R^{A7} are each independently a hydrogen atom or an aliphatic hydrocarbon group having 1 to 5 carbon atoms; n^{A8} is an integer of 1 to 8 and * represents a binding site.

Examples of the aliphatic hydrocarbon group having 1 to 5 carbon atoms and the halogen atom represented by R^{A6} and R^{A7} in the general formula (A-6) are the same as the examples of the aliphatic hydrocarbon group having 1 to 5 carbon atoms and the halogen atom represented by R^{A1}.

When n^{A8} in the general formula (A-6) is an integer of 2 or more, a plurality of R^{A6} is or a plurality of R^{A7}'s may be the same as or different from each other.

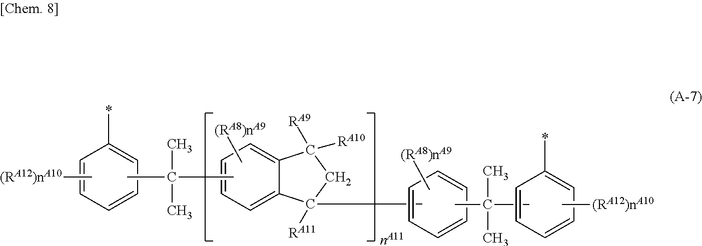

In the formula, R^{A8} is an alkyl group having 1 to 10 carbon atoms, an alkyloxy group having 1 to 10 carbon atoms, an alkylthio group having 1 to 10 carbon atoms, an aryl group having 6 to 10 carbon atoms, an aryloxy group having 6 to 10 carbon atoms, an arylthio group having 6 to 10 carbon atoms, a cycloalkyl group having 3 to 10 carbon atoms, a halogen atom, a hydroxy group, or a mercapto group; n^{A9} is an integer of 0 to 3; R^{A9} to R^{A11} are each independently an alkyl group having 1 to 10 carbon atoms; each R^{A12} is independently an alkyl group having 1 to 10 carbon atoms, an alkyloxy group having 1 to 10 carbon atoms, an alkylthio group having 1 to 10 carbon atoms, an aryl group having 6 to 10 carbon atoms, an aryloxy group having 6 to 10 carbon atoms, an arylthio group having 6 to 10 carbon atoms, a cycloalkyl group having 3 to 10 carbon atoms, a halogen atom, a nitro group, a hydroxy group, or a mercapto group; each n^{A10} is independently an integer of 0 to 4; n^{A11} is a numerical value of 0.95 to 10.0; and * represents a bonding site.

Examples of the alkyl group having 1 to 10 carbon atoms represented by R^{A8} in the general formula (A-7) include a methyl group, an ethyl group, a propyl group, a butyl group, a pentyl group, a hexyl group, a heptyl group, an octyl group, and a decyl group. These alkyl groups may be either linear or branched.

Examples of the alkyl groups included in the alkyloxy group having 1 to 10 carbon atoms and the alkylthio group having 1 to 10 carbon atoms represented by R^{A8} are the same as the examples of the alkyl group having 1 to 10 carbon atoms.

Examples of the aryl group having 6 to 10 carbon atoms represented by R^{A8} include a phenyl group and a naphthyl group.

Examples of the aryl groups included in the aryloxy group having 6 to 10 carbon atoms and the arylthio group having 6 to 10 carbon atoms represented by R^{A8} are the same as the examples of the aryl group having 6 to 10 carbon atoms.

Examples of the cycloalkyl group having 3 to 10 carbon atoms represented by R^{A8} include a cyclopropyl group, a cyclobutyl group, a cyclopentyl group, a cyclohexyl group, a cycloheptyl group, a cyclooctyl group, and a cyclodecyl group.

Examples of the alkyl group having 1 to 10 carbon atoms represented by R^{A9} to R^{A11} are the same as the examples of the alkyl group having 1 to 10 carbon atoms represented by R^{A8}. Of these, R^{A9} to R^{A11} are preferably an alkyl group having 1 to 4 carbon atoms, more preferably a methyl group or an ethyl group, and still more preferably a methyl group.

In the general formula (A-7), n^{A9} is an integer of 0 to 3, and when n^{A9} is 2 or 3, a plurality of R^{A8}'s may be the same as or different from each other.

Of these, from the viewpoint of compatibility with other resins, solvent solubility, dielectric characteristics, adhesion to conductors, and ease of production, the divalent organic group represented by the general formula (A-7) is preferably a divalent organic group in which n^{A9} is 0 and R^{A9} to R^{A1} are each a methyl group.

In the general formula (A-7), a plurality of R^{A8}'s, a plurality of R^{A12}'s, a plurality of n^{A9}'s, and a plurality of n^{A10}'s may be the same as or different from each other, respectively. In addition, when n^{A11} is greater than 1, a plurality of R^{A9}'s, a plurality of R^{A10}'s, and a plurality of R^{A11}'s may be the same as or different from each other, respectively.

The description of the alkyl group having 1 to 10 carbon atoms, the alkyloxy group having 1 to 10 carbon atoms, the alkylthio group having 1 to 10 carbon atoms, the aryl group having 6 to 10 carbon atoms, the aryloxy group having 6 to 10 carbon atoms, the arylthio group having 6 to 10 carbon atoms, and the cycloalkyl group having 3 to 10 carbon atoms represented by R^{A12} in the general formula (A-7) is the same as the description of the alkyl group having 1 to 10 carbon atoms, the alkyloxy group having 1 to 10 carbon atoms, the alkylthio group having 1 to 10 carbon atoms, the aryl group having 6 to 10 carbon atoms, the aryloxy group having 6 to 10 carbon atoms, the arylthio group having 6 to 10 carbon atoms, and the cycloalkyl group having 3 to 10 carbon atoms represented by R^{A8}.

Of these, from the viewpoint of compatibility with other resins, solvent solubility, dielectric characteristics, adhesion to conductors, and ease of production, R^{A12} is preferably an alkyl group having 1 to 4 carbon atoms, a cycloalkyl group having 3 to 6 carbon atoms, or an aryl group having 6 to 10 carbon atoms, and more preferably an alkyl group having 1 to 3 carbon atoms.

In the general formula (A-7), n^{A10} is an integer of 0 to 4, and from the viewpoint of compatibility with other resins, solvent solubility, dielectric characteristics, adhesion to conductors, and ease of production, n^{A10} is preferably an integer of 0 to 3, and more preferably 0 or 2.

From the viewpoint of compatibility with other resins, solvent solubility, melt viscosity, handleability, and heat resistance, n^{A11} in the general formula (A-7) is preferably 0.98 to 8.0, more preferably 1.0 to 7.0, and still more preferably 1.1 to 6.0.

Preferred examples of the divalent organic group represented by the general formula (A-7) include a divalent organic group represented by the following general formula (A-7-1), a divalent organic group represented by the following general formula (A-7-2), a divalent organic group represented by the following general formula (A-7-3), and a divalent organic group represented by the following general formula (A-7-4).

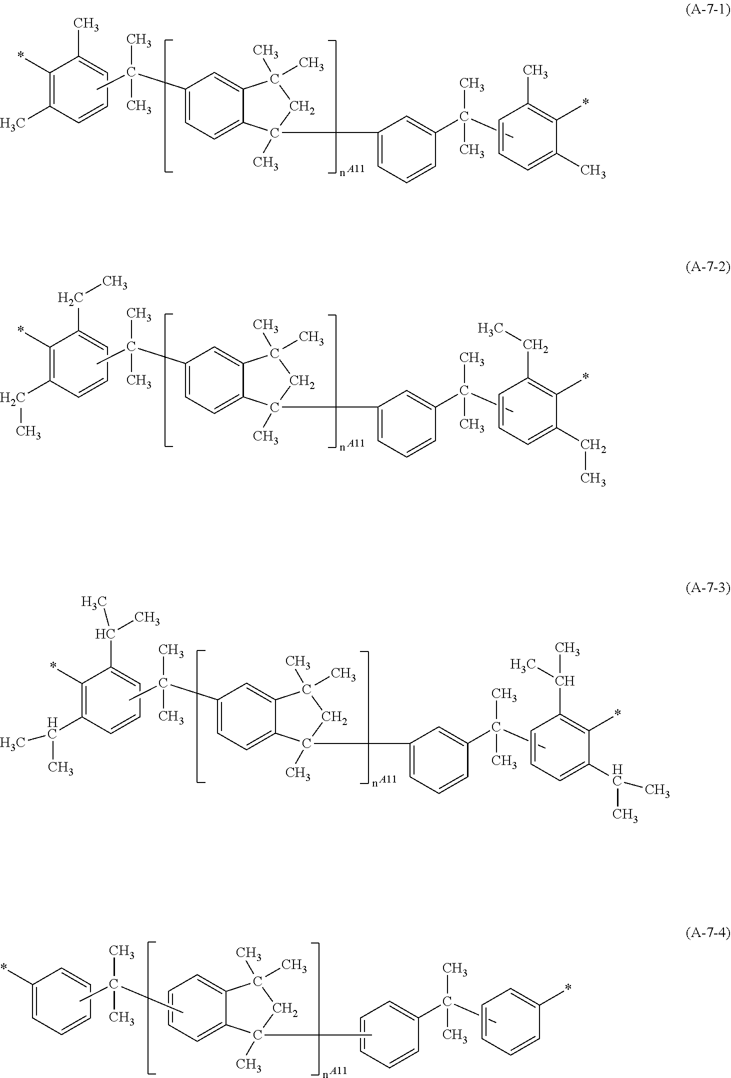

In the formulae, n^{A1} is the same as defined in the general formula (A-7); and * represents a bonding site.

Examples of the maleimide resin (AX) include an aromatic bismaleimide resin, an aromatic polymaleimide resin, and an aliphatic maleimide resin, and of these, an aromatic bismaleimide resin is preferred.

Specific examples of the maleimide resin (AX) include bis(4-maleimidophenyl)methane, m-phenylenebismaleimide, 2,2-bis[4-(4-maleimidophenoxy)phenyl]propane, 4-methyl-1,3-phenylenebismaleimide, 3,3′-dimethyl-5,5′-diethyl-4,4′-diphenylmethanebismaleimide, polyphenylmethane maleimide, an aromatic bismaleimide resin having an indane skeleton, and a biphenyl aralkyl type maleimide resin. Of these, an aromatic bismaleimide resin having an indane skeleton and a biphenyl aralkyl type maleimide resin are preferred.

The aromatic bismaleimide resin having an indane skeleton is preferably the maleimide resins represented by the general formula (A-1) in which X^{A1} is represented by the divalent organic group represented by the general formula (A-7) (hereinafter also referred to as “maleimide resin (A1)”).

The biphenyl aralkyl type maleimide resin is preferably the maleimide resin represented by the general formula (A-1) in which X^{A1} is represented by the divalent organic group represented by the general formula (A-5) (hereinafter also referred to as “maleimide resin (A2)”).

The content ratio of the maleimide resin (A1) to the maleimide resin (A2) is not particularly limited, and from the viewpoint of heat resistance and dielectric characteristics, it is preferably 30:70 to 95:5, more preferably 50:50 to 90:10, and still more preferably 70:30 to 80:20 on a mass basis.

Further, the total content of the maleimide resin (A1) and the maleimide resin (A2) in the thermosetting resin (A) is not particularly limited, and from the viewpoint of heat resistance and dielectric characteristics, it is preferably 60 to 100 mass %, more preferably 70 to 100 mass %, and still more preferably 80 to 100 mass %.

### (Maleimide Resin Derivative (AY))

The maleimide resin derivative (AY) is preferably an aminomaleimide resin having a structure derived from the maleimide resin (AX) and a structure derived from a diamine compound.

The aminomaleimide resin has the structure derived from the maleimide resin (AX) and a structure derived from a diamine compound.

The aminomaleimide resin is obtained by, for example, Michael addition of the maleimide resin (AX) and a diamine compound.

As the diamine compound, for example, a compound that is the same as an amine compound having at least two primary amino groups in one molecule described in JP 2020-200406 A can be used. Of these, 4,4′-diaminodiphenylmethane, 3,3′-dimethyl-4,4′-diaminodiphenylmethane, 3,3′-diethyl-4,4′-diaminodiphenylmethane, 2,2-bis[4-(4-aminophenoxy)phenyl]propane, 4,4′-[1,3-phenylenebis(1-methylethylidene)]bisanilne, 4,4′-[1,4-phenylenebis(1-methylethylidene)]bisanilne, and 3,3′-diethyl-4,4′-diaminodiphenylmethane are preferred.

### (Content of Thermosetting Resin (A))

The content of the thermosetting resin (A) in the resin composition of the present embodiment is not particularly limited, and is preferably 30 to 90 mass %, more preferably 50 to 85 mass %, and still more preferably 60 to 80 mass %, with respect to the total amount (100 mass %) of resin components in the resin composition of the present embodiment.

When the content of the thermosetting resin (A) is equal to or more than the lower limit value, the heat resistance, the moldability, the processability, and the adhesion to conductors tend to be easily improved. When the content of the thermosetting resin (A) is equal to or less than the upper limit value, the dielectric characteristics tend to be easily improved.

Here, in the present description, the “resin component” means a resin and a compound that forms a resin by a curing reaction.

In the resin composition of the present embodiment, for example, the component (A) corresponds to the resin component.

When the resin composition of the present embodiment contains, as an optional component, a resin or a compound that forms a resin by a curing reaction in addition to the above-mentioned components, these optional components are also included in the resin component. Examples of the optional resin component include a component (D) and a component (E) to be described later.

Meanwhile, the component (B), the component (C), a component (F), and a component (G) are not included in the resin component.

The content of the resin component in the resin composition of the present embodiment is not particularly limited, and is preferably 30 to 85 mass %, more preferably 50 to 80 mass %, and still more preferably 60 to 75 mass %, with respect to the total amount (100 mass %) of the solid content of the resin composition of the present embodiment.

When the content of the resin component is equal to or more than the lower limit value, the heat resistance, the moldability, the processability, and the adhesion to conductors tend to be easily improved. When the content of the resin component is equal to or less than the upper limit value, the low thermal expansion properties tend to be easily improved.

<(B) Inorganic Filler Having True Density of 1,500 kg/m³ or Less>

The resin composition of the present embodiment contains an inorganic filler having a true density of 1,500 kg/m³ or less as the component (B).

Here, the true density in the present embodiment is a value measured with a dry type automatic pycnometer “AccuPyc II 1340” (manufactured by Shimadzu Corporation), and is more particularly a value measured in accordance with a method described in Examples.

In the present description, the “inorganic filler” means a filler containing an inorganic element.

The component (B) may be used alone, or two or more kinds thereof may be used in combination.

The true density of the component (B) is preferably 1,000 to 1,500 kg/m³, more preferably 1,100 to 1,450 kg/m³, and still more preferably 1,200 to 1,400 kg/m³.

When the true density of the component (B) is equal to or more than the lower limit value, the low thermal expansion properties tend to be easily improved. When the true density of the component (B) is equal to or less than the upper limit value, the relative permittivity (Dk) tends to be easily improved.

The component (B) may be a solid particle or a hollow particle, and a solid particle is preferred. In the present description, the “hollow particle” means a particle containing an outer shell and a void having a diameter of 100 nm or more in the outer shell, and the “solid particle” means a particle that is not the hollow particle. The presence of the outer shell and the diameter of the void are observed with an electron microscope.

Examples of a material for the component (B) include silica, alumina, titanium oxide, mica, beryllia, barium titanate, potassium titanate, strontium titanate, calcium titanate, aluminum carbonate, magnesium hydroxide, aluminum hydroxide, aluminum silicate, calcium carbonate, calcium silicate, magnesium silicate, silicon nitride, boron nitride, clay, talc, aluminum borate, silicon carbide, and silsesquioxane. Of these, the material for the component (B) is preferably a silicon-containing compound having a silicon atom, more preferably a particle having a siloxane bond (hereinafter also referred to as “siloxane particle”), and still more preferably silica or silsesquioxane.

A silicon-containing compound having a true density of 1,500 kg/m³ or less preferably has a —Si—O— bond and a Si—R bond (wherein R represents an organic group). The —Si—O— bond contributes to low thermal expansion properties, and the —Si—R bond reduces the true density of the silicon-containing compound and contributes to a reduction in relative permittivity (Dk).

The component (B) may be surface-treated with a surface treatment agent such as a coupling agent, or may not be surface-treated with a surface treatment agent, but the component surface-treated with a surface treatment agent is preferred.

Examples of the surface treatment agent include a silane coupling agent and a titanate coupling agent. Of these, a silane coupling agent is preferred.

Examples of the silane coupling agent include aminosilane-based coupling agents (hereinafter also simply referred to as “aminosilane”) such as N-phenyl-γ-aminopropyltrimethoxysilane, N-phenyl-γ-aminopropyltriethoxysilane, γ-aminopropyltrimethoxysilane, γ-aminopropyltriethoxysilane, γ-(2-aminoethyl)aminopropyltrimethoxysilane, γ-(2-aminoethyl)aminopropyltriethoxysilane, γ-anilinopropyltrimethoxysilane, γ-anilinopropyltriethoxysilane, N-β-(N-vinylbenzylaminoethyl)-γ-aminopropyltrimethoxysilane, and N-β-(N-vinylbenzylaminoethyl)-γ-aminopropyltriethoxysilane; isocyanate silane-based coupling agents (hereinafter also simply referred to as “isocyanatesilane”) such as 3-isocyanate propyltrimethoxysilane and 3-isocyanate propyltriethoxysilane; (meth)acryl silane-based coupling agents (hereinafter also simply referred to as “(meth)acrylsilane”) such as 3-(methacryloyloxy)propyltrimethoxysilane and 3-(methacryloyloxy)propyltriethoxysilane; vinyl silane-based coupling agents (hereinafter also simply referred to as “vinyl silane”) such as vinyltrimethoxysilane and vinyltriethoxysilane; epoxysilane-based coupling agents such as γ-glycidyloxypropyltrimethoxysilane and γ-glycidyloxypropyltriethoxysilane; phenylsilane-based coupling agents, alkylsilane-based coupling agents, alkynylsilane-based coupling agents, haloalkylsilane-based coupling agents, siloxane-based coupling agents, hydrosilane-based coupling agents, silazane-based coupling agents, alkoxysilane-based coupling agents, chlorosilane-based coupling agents, isocyanurate silane-based coupling agents, ureidosilane-based coupling agents, mercaptosilane-based coupling agents, and sulfidesilane-based coupling agents. Of these, a vinyl silane-based coupling agent is preferred.

The average particle diameter (D₅₀) of the component (B) is not particularly limited, and from the viewpoint of dispersibility of the component (B) and fine wiring properties, it is preferably 0.1 to 3 μm, more preferably 0.3 to 2 μm, and still more preferably 0.5 to 1 μm.

In the present description, the average particle diameter (D₅₀) represents a particle diameter corresponding to a volume of 50% in a cumulative frequency distribution curve of particle diameter when the whole volume of particles is 100%. The average particle diameter (D₅₀) can be measured with, for example, a particle size distribution measuring device using a laser diffraction and scattering method.

The content of the component (B) in the resin composition of the present embodiment is not particularly limited, and is preferably 1 to 30 mass %, more preferably 5 to 20 mass %, and still more preferably 10 to 15 mass %, with respect to the total amount (100 mass %) of the solid content of the resin composition.

When the content of the component (B) is equal to or more than the lower limit value, the low thermal expansion properties and the dielectric characteristics tend to be easily improved. When the content of the component (B) is equal to or less than the upper limit value, the moldability and the adhesion to conductors tend to be easily improved.

<(C) Inorganic Filler Having True Density of More than 1,500 kg/m³>

The resin composition of the present embodiment contains an inorganic filler having a true density of more than 1,500 kg/m³ as the component (C).

The component (C) may be used alone, or two or more kinds thereof may be used in combination.

The true density of the component (C) is preferably 1,600 to 4,000 kg/m³, more preferably 1,800 to 3,000 kg/m³, and still more preferably 2,000 to 2,300 kg/m³.

When the true density of the component (C) is equal to or more than the lower limit value, the laser processability and the low thermal expansion properties tend to be easily improved. When the true density of the component (C) is equal to or less than the upper limit value, the dielectric characteristics tend to be easily improved.

The difference between the true density of the component (B) and the true density of the component (C) (true density of component (C)−true density of component (B)) is not particularly limited, and is preferably 400 to 1,000 kg/m³, more preferably 500 to 800 kg/m³, and still more preferably 600 to 700 kg/m³.

When the difference in true density falls within the above-mentioned range, both the dielectric characteristics and the laser processability tend to be highly achieved.

Examples of a material for the component (C) are the same as the examples of the material for the component (B). Of these, from the viewpoint of laser processability and low thermal expansion properties, a silicon-containing compound is preferred, and silica is more preferred.

The component (C) may be surface-treated with a surface treatment agent such as a coupling agent, or may not be surface-treated with a surface treatment agent, but the component surface-treated with a surface treatment agent is preferred. Examples of the surface treatment agent are the same as the examples shown in the description of the component (B). Of these, from the viewpoint of laser processability, an aminosilane-based coupling agent is preferred, and aminosilane having an amino group replaced by a phenyl group (hereinafter also referred to as “aminophenylsilane”) is more preferred.

Here, a metal-clad layered sheet is subjected to desmear treatment in which an insulating layer is treated with an oxidizing agent aqueous solution for removal of a residue component after laser processing or surface-roughening to improve the adhesion of the insulating layer to a conductor layer. At that time, in a metal-clad layered sheet formed using the resin composition having a reduced relative permittivity, a hollow having a diameter of more than several tens of nanometers may be generated on the surface of the insulating layer after the desmear treatment. In addition, before curing the resin composition having a reduced relative permittivity, a separated part of the component may be observed, that is, the compatibility of the resin composition may be lower than the compatibility of each of the components.

When one or more selected from the group consisting of a vinyl silane-based coupling agent and an aminosilane-based coupling agent are used as the surface treatment agent of the component (B) and an aminosilane-based coupling agent is used as the surface treatment agent of the component (C), the compatibility of the resin composition can be improved, and the generation of the hollow can be suppressed.

The average particle diameter (D₅₀) of the component (C) is not particularly limited, and from the viewpoint of dispersibility of the component (C) and fine wiring properties, it is preferably 0.05 to 3 μm, more preferably 0.1 to 2 μm, and still more preferably 0.3 to 1 μm.

The content of the component (C) in the resin composition of the present embodiment is not particularly limited, and is preferably 2 to 40 mass %, more preferably 8 to 30 mass %, and still more preferably 15 to 20 mass %, with respect to the total amount (100 mass %) of the solid content of the resin composition.

When the content of the component (C) is equal to or more than the lower limit value, the laser processability, the low thermal expansion properties, the heat resistance, and the flame resistance tend to be easily improved. When the content of the component (C) is equal to or less than the upper limit value, the moldability and the adhesion to conductors tend to be easily improved.

The content ratio of the component (B) to the component (C) (component (B):component (C)) in the resin composition of the present embodiment is not particularly limited, and is preferably 20:80 to 80:20, more preferably 30:70 to 70:30, and still more preferably 40:60 to 60:40 on a mass basis.

When the content ratio falls within the above-mentioned range, both the relative permittivity (Dk) and the laser processability tend to be highly achieved.

<(D) One or More Selected from the Group Consisting of Conjugated Diene Polymer and Modified Conjugated Diene Polymer>

It is preferable that the resin composition of the present embodiment further contain (D) one or more selected from the group consisting of a conjugated diene polymer and a modified conjugated diene polymer (hereinafter also referred to as “diene-based polymer (D)”).

When the resin composition of the embodiment contains the component (D), more excellent dielectric characteristics tend to be easily achieved.

The component (D) may be used alone, or two or more kinds thereof may be used in combination.

### (Conjugated Diene Polymer)

In the present description, the “conjugated diene polymer” means a polymer of a conjugated diene compound.

When the resin composition of the present embodiment contains the conjugated diene polymer, more excellent dielectric characteristics tend to be easily achieved.

Examples of a conjugated diene compound that is a monomer component of the conjugated diene polymer include 1,3-butadiene, isoprene, 1,3-pentadiene, 2,3-dimethyl-1,3-butadiene, 2-phenyl-1,3-butadiene, and 1,3-hexadiene.

The conjugated diene polymer may be a polymer of one kind of conjugated diene compound or a copolymer of two or more kinds of conjugated diene compounds.

The conjugated diene polymer may be a copolymer of one or more kinds of conjugated diene compounds and one or more kinds of monomers other than the conjugated diene compounds.

When the conjugated diene polymer is a copolymer, a polymerization form is not particularly limited, and may be any one of random polymerization, block polymerization, or graft polymerization.

From the viewpoint of compatibility with other resins and dielectric characteristics, the conjugated diene polymer is preferably a conjugated diene polymer having a vinyl group on a side chain.

The number of side-chain vinyl groups per molecule of the conjugated diene polymer is not particularly limited, and from the viewpoint of compatibility with other resins and dielectric characteristics, it is preferably 2 or more, more preferably 5 or more, and still more preferably 10 or more.

The upper limit of the number of side-chain vinyl groups per molecule of the conjugated diene polymer is not particularly limited, and may be, for example, 100 or less, 80 or less, or 60 or less.

Examples of the conjugated diene polymer include a polybutadiene having a 1,2-vinyl group, and a butadiene-styrene copolymer having a 1,2-vinyl group. Of these, from the viewpoint of dielectric characteristics and heat resistance, a polybutadiene having a 1,2-vinyl group and a butadiene-styrene copolymer having a 1,2-vinyl group are preferred, and a polybutadiene having a 1,2-vinyl group is more preferred. The polybutadiene having a 1,2-vinyl group is preferably a polybutadiene homopolymer having a 1,2-vinyl group.

A 1,2-vinyl group derived from butadiene in the conjugated diene polymer is a vinyl group contained in a structural unit derived from butadiene represented by the following formula (D-1).

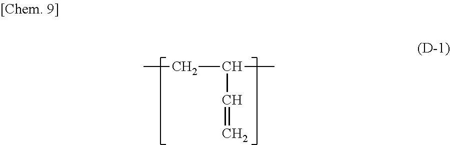

When the conjugated diene polymer is a polybutadiene having a 1,2-vinyl group, the content of a structural unit having a 1,2-vinyl group with respect to the whole structural unit derived from butadiene constituting a polybutadiene (hereinafter also referred to as “vinyl group content ratio”) is not particularly limited. From the viewpoint of compatibility with other resins, dielectric characteristics, and heat resistance, it is preferably 50 mol % or more, more preferably 70 mol % or more, and still more preferably 85 mol % or more. In addition, the upper limit of the vinyl group content ratio is not particularly limited, and may be 100 mol % or less, 95 mol % or less, or 90 mol % or less. The structural unit having a 1,2-vinyl group is preferably a structural unit derived from butadiene represented by the formula (D-1).

From the same viewpoint, the polybutadiene having a 1,2-vinyl group is preferably a 1,2-polybutadiene homopolymer.

The number-average molecular weight (Mn) of the conjugated diene polymer is not particularly limited, and from the viewpoint of compatibility with other resins, dielectric characteristics, and heat resistance, it is preferably 400 to 3,000, more preferably 600 to 2,000, and still more preferably 800 to 1,500.

### (Modified Conjugated Diene Polymer)

The modified conjugated diene polymer is a polymer obtained by modifying a conjugated diene polymer.

When the resin composition of the present embodiment contains the modified conjugated diene polymer, more excellent dielectric characteristics tend to be easily achieved in addition to satisfactory heat resistance and low thermal expansion properties.

The modified conjugated diene polymer may be used alone, or two or more kinds thereof may be used in combination.

From the viewpoint of compatibility with other resins, dielectric characteristics, and adhesion to conductors, the modified conjugated diene polymer is preferably a modified conjugated diene polymer obtained by modifying a conjugated diene polymer having a vinyl group on a side chain with a maleimide resin having two or more N-substituted maleimide groups (hereinafter also referred to as “maleimide resin for modification”).

As the conjugated diene polymer having a vinyl group on a side chain, for example, the conjugated diene polymer having a vinyl group on a side chain described as the conjugated diene polymer can be used, and preferable aspects of the conjugated diene polymer are the same as those of the conjugated diene polymer.

The conjugated diene polymer having a vinyl group on a side chain may be used alone, or two or more kinds thereof may be used in combination.

As the maleimide resin for modification, for example, the maleimide resin having two or more N-substituted maleimide groups described as the component (A) can be used.

The modified conjugated diene polymer preferably has on a side chain a substituent (hereinafter also referred to as “maleimide resin-derived substituent”) obtained by a reaction of a side-chain vinyl group of the conjugated diene polymer having a vinyl group on a side chain with an N-substituted maleimide group of the maleimide resin for modification, and more preferably has a maleimide resin-derived substituent and a vinyl group on a side chain.

From the viewpoint of compatibility with other resins, dielectric characteristics, low thermal expansion properties, and heat resistance, the maleimide resin-derived substituent is preferably a group having a structure represented by the following general formula (D-2) or (D-3) as a structure derived from the maleimide resin for modification.

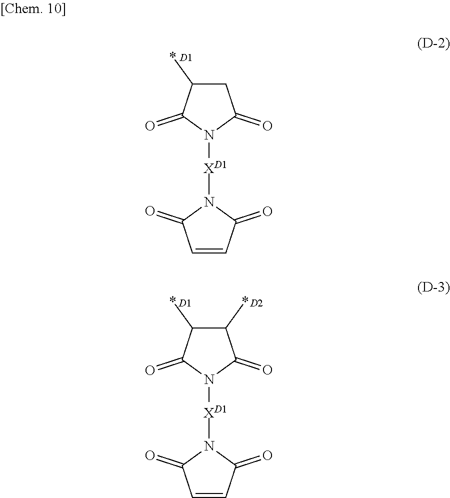

In the formula, X^{D1} is a divalent group obtained by removing two N-substituted maleimide groups from a maleimide resin having two or more N-substituted maleimide groups, *^{D1} is a site that binds to a carbon atom derived from a side-chain vinyl group of a conjugated diene polymer having a vinyl group on a side chain, and *^{D2} is a site that binds to another atom.

The extent to which the maleimide resin-derived substituent is present in the modified conjugated diene polymer may be an indicator of the extent to which the vinyl group of the conjugated diene polymer having a vinyl group on a side chain is modified by the maleimide resin for modification.

The modification ratio of vinyl group is not particularly limited, and from the viewpoint of compatibility with other resins, dielectric characteristics, low thermal expansion properties, and heat resistance, it is preferably 20 to 70%, more preferably 30 to 60%, and further preferably 35 to 50%. Here, the modification ratio of vinyl group is a value determined by a method described in Examples.

The vinyl group of the modified conjugated diene polymer is preferably a 1,2-vinyl group of a structural unit derived from butadiene.

The number-average molecular weight (Mn) of the modified conjugated diene polymer is not particularly limited, and from the viewpoint of compatibility with other resins, dielectric characteristics, low thermal expansion properties, and heat resistance, it is preferably 700 to 6,000, more preferably 800 to 5,000, and still more preferably 1,000 to 2,500.

A condition of a reaction of the conjugated diene polymer with the maleimide resin for modification is not particularly limited. For example, a raw material and an organic solvent are placed in a reaction vessel, and allowed to react with each other with heating, stirring, or the like, as required, to obtain the modified conjugated diene polymer.

The ratio (Mm/Mv) of the amount by mole (Mm) of the N-substituted maleimide group of the maleimide resin for modification to the amount by mole (Mv) of the side-chain vinyl group of the conjugated diene polymer having a vinyl group on a side chain during the reaction is not particularly limited. From the viewpoint of compatibility with other resins of the modified conjugated diene polymer to be obtained and suppression of gelation of a product in the reaction, the ratio is preferably 0.001 to 0.5, more preferably 0.005 to 0.1, and still more preferably 0.008 to 0.05.

When the resin composition of the present embodiment contains the component (D), the content of the component (D) is not particularly limited, and is preferably 1 to 40 mass %, more preferably 10 to 35 mass %, and still more preferably 15 to 30 mass % with respect to the total amount (100 mass %) of the resin components in the resin composition of the present embodiment.

When the content of the component (D) is equal to or more than the lower limit value, the dielectric characteristics tend to be easily improved. When the content of the component (D) is equal to or less than the upper limit value, the heat resistance and the flame resistance tend to be easily improved.

### <(E) Styrene-Based Thermoplastic Resin>

It is preferable that the resin composition of the present embodiment further contain (E) a styrene-based thermoplastic resin.

When the resin composition of the present embodiment contains the styrene-based thermoplastic resin (E), the dielectric characteristics tend to be improved.

The styrene-based thermoplastic resin (E) may be used alone, or two or more kinds thereof may be used in combination.

The styrene-based thermoplastic resin (E) has a structural unit derived from a styrene-based compound (hereinafter sometimes referred to as “styrene-based unit”).

Examples of the styrene-based compound include styrene; and alkyl-substituted styrene such as α-methylstyrene, o-methylstyrene, m-methylstyrene, and p-methylstyrene.

The number of carbon atoms of an alkyl group of the alkyl-substituted styrene is preferably 1 to 5, more preferably 1 to 3, and still more preferably 1 or 2.

The styrene-based thermoplastic resin (E) may have a structural unit other than the styrene-based unit.

Examples of the structural unit other than the styrene-based unit include a structural unit derived from butadiene, a structural unit derived from isoprene, structural unit derived from maleic acid, and a structural unit derived from maleic anhydride. The structural unit derived from butadiene and the structural unit derived from isoprene may be hydrogenated. When the structural unit is hydrogenated, the structural unit derived from butadiene is a structural unit in which an ethylene unit and a butylene unit are mixed, and the structural unit derived from isoprene is a structural unit in which an ethylene unit and a propylene unit are mixed.

Examples of the styrene-based thermoplastic resin (E) include a hydrogenated product of a styrene-butadiene-styrene block copolymer, a hydrogenated product of a styrene-isoprene-styrene block copolymer, and a styrene-maleic anhydride copolymer.

Examples of the hydrogenated product of a styrene-butadiene-styrene block copolymer include SEBS obtained by complete hydrogenation of a carbon-carbon double bond in a butadiene block and SBBS obtained by partial hydrogenation of a carbon-carbon double bond at a 1,2-binding site in a butadiene block. The hydrogenated product of a styrene-isoprene-styrene block copolymer is obtained as SEPS by hydrogenation of a polyisoprene moiety. Of these, from the viewpoint of dielectric characteristics, adhesion to conductors, heat resistance, glass transition temperature, and low thermal expansion properties, SEBS and SEPS are preferred, and SEBS is more preferred.

From the viewpoint of dielectric characteristics, adhesion to conductors, heat resistance, and low thermal expansion properties, the content ratio of the styrene-based unit in the styrene-based thermoplastic resin (E) (hereinafter sometimes referred to as “styrene content ratio”) is preferably 5 to 60 mass %, more preferably 7 to 40 mass %, and still more preferably 10 to 20 mass %.

The number-average molecular weight (Mn) of the styrene-based thermoplastic resin (E) is not particularly limited, and is preferably 10,000 to 500,000, more preferably 50,000 to 350,000, and still more preferably 100,000 to 200,000.

When the resin composition of the present embodiment contains the styrene-based thermoplastic resin (E), the content of the styrene-based thermoplastic resin (E) is preferably 1 to 30 mass %, more preferably 2 to 20 mass %, and still more preferably 3 to 10 mass %, with respect to the total amount (100 mass %) of the resin components in the resin composition of the present embodiment.

When the content of the styrene-based thermoplastic resin (E) is equal to or more than the lower limit value, the dielectric characteristics tend to be easily improved. When the content of the styrene-based thermoplastic resin (E) is equal to or less than the upper limit value, the heat resistance and the flame resistance tend to be easily improved.

### <(F) Flame Retardant>

It is preferable that the resin composition of the present embodiment further contain a flame retardant (F).

When the resin composition of the present embodiment contains the flame retardant (F), the flame resistance tends to be improved.

The flame retardant (F) may be used alone, or two or more kinds thereof may be used in combination. Furthermore, a flame retardant promoter may be contained as required.

Examples of the flame retardant (F) include a phosphorus-based flame retardant, a metal hydrate, and a halogen-based flame retardant.

The phosphorus-based flame retardant may be an inorganic phosphorus-based flame retardant or an organic phosphorus-based flame retardant.

Examples of the inorganic phosphorus-based flame retardant include red phosphorous; ammonium phosphates such as monoammonium phosphate, diammonium phosphate, triammonium phosphate, and ammonium polyphosphate; inorganic nitrogen-containing phosphorus compounds such as phosphoramide; phosphoric acid; and phosphine oxide.

Examples of the organic phosphorus-based flame retardant include an aromatic phosphate ester compound, a mono-substituted phosphonic acid diester compound, a di-substituted phosphinic acid ester compound, a metal salt of di-substituted phosphinic acid, an organic nitrogen-containing phosphorus compound, and a cyclic organic phosphorus compound. Of these, an aromatic phosphate ester compound is preferred.

Examples of the aromatic phosphate ester compound include triphenyl phosphate, tricresyl phosphate, trixylenyl phosphate, cresyl diphenyl phosphate, cresyl di-2,6-xylenyl phosphate, resorcinol bis(diphenyl phosphate), 1,3-phenylene bis(di-2,6-xylenyl phosphate), bisphenol Abis(diphenyl phosphate), 1,3-phenylene bis(diphenyl phosphate), and 4,4′-biphenol bis(di-2,6-xylenyl phosphate). Of these, 4,4′-biphenol bis(di-2,6-xylenyl phosphate) is preferred.

Examples of the metal hydrate include a hydrate of aluminum hydroxide and a hydrate of magnesium hydroxide.

Examples of the halogen-based flame retardant include a chlorine-based flame retardant and a bromine-based flame retardant.

When the resin composition of the present embodiment contains the flame retardant (F), the content of the flame retardant (F) is not particularly limited, and is preferably 1 to 30 parts by mass, more preferably 3 to 20 parts by mass, and still more preferably 5 to 12 parts by mass, with respect to 100 parts by mass of the sum of the resin components in the resin composition of the present embodiment.

When the content of the flame retardant (F) is equal to or more than the lower limit value, the flame resistance tends to be easily improved. When the content of the flame retardant (F) is equal to or less than the upper limit value, the dielectric characteristics, the moldability, and the adhesion to conductors tend to be easily improved.

### <(G) Curing Accelerator>

It is preferable that the resin composition of the embodiment further contain a curing accelerator (G).

When the resin composition of the present embodiment contains the curing accelerator (G), curing properties are improved, and more excellent dielectric characteristics, heat resistance, and adhesion to conductors tend to be easily achieved.

The curing accelerator (G) may be used alone, or two or more kinds thereof may be used in combination.

Examples of the curing accelerator (G) include acidic catalysts such as p-toluenesulfonic acid; amine compounds such as triethylamine, tributylamine, pyridine, and dicyandiamide; imidazole compounds such as methylimidazole, phenylimidazole, 1-cyanoethyl-2-phenylimidazole, and 1-cyanoethyl-2-phenylimidazolium trimellitate; isocyanate-masked imidazole compounds such as an addition reaction product of hexamethylene diisocyanate resin and 2-ethyl-4-methylimidazole; quaternary ammonium compounds; phosphorus-based compounds such as triphenyl phosphine; organic peroxides such as dicumyl peroxide, 2,5-dimethyl-2,5-bis(t-butylperoxy)hexine-3, 2,5-dimethyl-2,5-bis(t-butylperoxy)hexane, t-butylperoxy isopropyl monocarbonate, and α,α′-bis(t-butylperoxy)diisopropylbenzene; and carboxylate salts of manganese, cobalt, and zinc. Of these, an imidazole compound and an organic peroxides are preferred.

### (Content of Curing Accelerator (G))

When the resin composition of the present embodiment contains the curing accelerator (G), the content of the curing accelerator (G) is not particularly limited, and is preferably 0.1 to 20 parts by mass, more preferably 0.5 to 10 parts by mass, and still more preferably 1 to 5 parts by mass, with respect to the total amount (100 parts by mass) of the resin components in the resin composition of the present embodiment.

When the content of the curing accelerator (G) is equal to or more than the lower limit value, a sufficient curing accelerating effect tends to be easily achieved. When the content of the curing accelerator (G) is equal to or less than the upper limit value, the storage stability tends to be easily improved.

### <Other Components>

The resin composition of the present embodiment may further contain one or more selected from the group consisting of a resin material other than the above-mentioned components, an antioxidant, a thermal stabilizer, an antistat, an ultraviolet absorber, a pigment, a colorant, a lubricant, an organic solvent, and other additives as required. Each of the components may be used alone, or two or more kinds thereof may be used in combination.

The usage amount of each of the components is not particularly limited, and each of the components may be used within a range that does not impair the effects of the embodiment as required.

### (Organic Solvent)

From the viewpoint of making handling easy and from the viewpoint of facilitating the production of a prepreg to be described later, the resin composition of the present embodiment may contain an organic solvent.

The organic solvent may be used alone, or two or more kinds thereof may be used in combination.

Examples of the organic solvent include: alcoholic solvents such as ethanol, propanol, butanol, methyl cellosolve, butyl cellosolve, and propylene glycol monomethyl ether; ketone-based solvents such as acetone, methyl ethyl ketone, methyl isobutyl ketone, and cyclohexanone; ether-based solvents such as tetrahydrofuran; aromatic hydrocarbon-based solvents such as toluene, xylene, and mesitylene; nitrogen atom-containing solvents such as dimethylformamide, dimethylacetamide, and N-methylpyrrolidone; sulfur atom-containing solvents such as dimethylsulfoxide; and ester-based solvents such as γ-butyrolactone.

Of these, from the viewpoint of solubility, an alcoholic solvent, a ketone-based solvent, a nitrogen atom-containing solvent, and an aromatic hydrocarbon-based solvent are preferred, an aromatic hydrocarbon-based solvent is more preferred, and toluene is still more preferred.

### <Method for Producing Resin Composition>

The resin composition of the present embodiment can be produced by mixing the above-mentioned components.

At the time of mixing the components, the components may be dissolved or dispersed with stirring. Further, conditions such as the order of mixing raw materials, the mixing temperature, and the mixing time are not particularly limited, and may be optionally set according to the kinds of the raw materials, and the like.

### [Prepreg]

A prepreg of the present embodiment is a prepreg containing the resin composition of the present embodiment or a semi-cured product of the resin composition.

The prepreg of the present embodiment contains, for example, the resin composition of the present embodiment or a semi-cured product of the resin composition and a sheet-shaped fiber base material.

As the sheet-shaped fiber base material contained in the prepreg of the present embodiment, for example, known sheet-shaped fiber base materials used in various layered sheets for electrical insulating materials can be used.

Examples of a material for the sheet-shaped fiber base material include inorganic fibers such as E glass, D glass, S glass, and Q glass; organic fibers such as polyimide, polyester, and tetrafluoroethylene; and mixtures thereof. These sheet-shaped fiber base materials have a shape of, for example, a woven fabric, a nonwoven fabric, a roving, a chopped strand mat, or a surfacing mat.

The prepreg of the present embodiment can be produced by, for example, impregnating the resin composition of the present embodiment into the sheet-shaped fiber base material or applying the resin composition to the sheet-shaped fiber base material, and then heating and drying the resin composition to make it B-stage.

The temperature and time of the heating and drying are not particularly limited, and from the viewpoint of productivity and appropriate B-staging of the resin composition of the present embodiment, for example, the temperature and time can be set to 50 to 200° C. and 1 to 30 minutes, respectively.

The content of the resin composition in the prepreg of the present embodiment is not particularly limited, and from the viewpoint of easily obtaining more satisfactory moldability when a layered sheet is formed, the content is preferably 20 to 90 mass %, more preferably 25 to 80 mass %, and still more preferably 30 to 75 mass %.

### [Resin Film]

A resin film of the present embodiment is a resin film containing the resin composition of the present embodiment or a semi-cured product of the resin composition.

The resin film of the present embodiment can be produced by, for example, applying the resin composition of the present embodiment containing an organic solvent to a support and then heating and drying the resin composition.

Examples of the support include a plastic film, a metal foil, and a release paper.

The temperature and time of the heating and drying are not particularly limited, and from the viewpoint of productivity and appropriate B-staging of the resin composition of the present embodiment, the temperature and time can be set to 50 to 200° C. and 1 to 30 minutes, respectively.

The resin film of the present embodiment is preferably used for forming an insulating layer in the case of producing a printed circuit board.

### [Layered Sheet]

A layered sheet of the present embodiment is a layered sheet including a cured product of the resin composition of the present embodiment, and a metal foil.

A layered sheet having a metal foil is sometimes referred to as a metal-clad layered sheet.

The metal of the metal foil is not particularly limited, and examples thereof include copper, gold, silver, nickel, platinum, molybdenum, ruthenium, aluminum, tungsten, iron, titanium, chromium, and an alloy containing one or more kinds of these metal elements.

The layered sheet of the present embodiment can be produced by, for example, disposing a metal foil on one surface or both surfaces of the prepreg of the present embodiment, and then subjecting the prepreg to heating and press molding.

Usually, the B-staged prepreg is cured by the heating and the press molding to obtain the layered sheet of the present embodiment.

At the time of performing heating and press molding, only one prepreg may be used, or two or more prepregs may be laminated and used.

For the heating and the press molding, for example, a multi-stage press, a multi-stage vacuum press, a continuous molding, or an autoclave molding machine can be used.

The conditions of the heating and the press molding are not particularly limited, and the temperature may be 100 to 300° C., the time may be 10 to 300 minutes, and the pressure may be 1.5 to 5 MPa, for example.

### [Printed Circuit Board]

A printed circuit board of the present embodiment is a printed circuit board including a cured product of the resin composition of the present embodiment.

The printed circuit board of the present embodiment can be produced by, for example, performing conductor circuit formation on one or more kinds of materials selected from the group consisting of a cured product of the prepreg of the present embodiment, a cured product and a layered sheet of the resin film of the present embodiment by a known method. In addition, a multilayer printed circuit board can also be produced by further performing a multilayer adhesion process as required. The conductor circuit can be formed by, for example, appropriately performing a drilling process, a metal plating process, or etching of a metal foil.

### [Semiconductor Package]

A semiconductor package of the present embodiment is a semiconductor package including the printed circuit board of the present embodiment and a semiconductor element.

The semiconductor package of the present embodiment can be produced by, for example, mounting a semiconductor chip, a memory, and the like on the printed circuit board of the present embodiment by a known method.

### EXAMPLES

Hereinafter, the present embodiment will be specifically described with reference to Examples. However, the present embodiment is not limited to the following Examples.

### [Method for Measuring Number-Average Molecular Weight (Mn)]

A number-average molecular weight was determined from a calibration curve using standard polystyrene by gel permeation chromatography (GPC). The calibration curve was approximated by a cubic equation using standard polystyrene: TSKstandard POLYSTYRENE (Type; A-2500, A-5000, F-1, F-2, F-4, F-10, F-20, F-40) (manufactured by Tosoh Corporation, product name). The measurement conditions of GPC are shown below.

### Apparatus:

Pump: L-6200 type (manufactured by Hitachi High-Technologies Corporation)
Detector: L-3300 type RI (manufactured by Hitachi High-Technologies Corporation)
Column oven: L-655A-52 (manufactured by Hitachi High-Technologies Corporation)
Column: guard column: TSK Guardcolumn HHR-L+column: TSKgel G400011HR+
TSKgel G2000HHR (all manufactured by Tosoh Corporation, product name)
Column size: 6.0×40 mm (guard column), 7.8×300 mm (column)
Eluent: tetrahydrofuran
Sample concentration: 30 mg/5 mL
Injection volume: 20 μL
Flow rate: 1.00 mL/min
Measurement temperature: 40° C.

### [Method for Measuring True Density of Inorganic Filler]

A cell for 1 cm³ of a dry type automatic pycnometer “AccuPycII 1340” (manufactured by Shimadzu Corporation) was filled with a measurement sample up to 80% of its volume. The weight of the cell filled with the measurement sample was measured, and from the weight, the weight of only the cell was subtracted to determine the weight of the measurement sample with which the cell was filled.

Next, the cell filled with the measurement sample was set in the dry type automatic pycnometer, and the weight of the measurement sample was input. The measurement sample was allowed to stand at normal temperature (25° C.) under a nitrogen atmosphere for 1 hour with the cell being set in the pycnometer, measurement was performed 10 times, and an average value thereof was determined as a true density.

### [Production of Modified Conjugated Diene Polymer]

### Production Example 1

A 2 L heatable and coolable glass flask equipped with a thermometer, a reflux condenser, and a stirrer was charged with 33.8 parts by mass of polybutadiene (1,2-polybutadiene homopolymer, number-average molecular weight (Mn): 1,200, vinyl group content: 85 mol % or more), 1.43 parts by mass of bismaleimide resin (aromatic bismaleimide resin having a group containing an indan ring, number-average molecular weight (Mn): 1,300, which is the same as a maleimide resin 1 to be described later), 0.0035 parts by mass of α,α′-bis(t-butylperoxy)diisopropylbenzene, and toluene as an organic solvent. Subsequently, a reaction was caused with stirring at 90 to 100° C. under a nitrogen atmosphere for 5 hours to obtain a solution of modified conjugated diene polymer (solid content concentration: 35 mass %). The number-average molecular weight (Mn) of the obtained conjugated diene polymer was 2,000.

A solution containing the polybutadiene and the bismaleimide resin before the initiation of the reaction and the solution after the reaction were subjected to GPC measurement by the above-mentioned method. A peak area derived from the bismaleimide resin before and after the reaction was determined. Subsequently, the modification ratio of vinyl group of the bismaleimide resin was calculated by the following equation. The modification ratio of vinyl group corresponds the decrease ratio of the peak area derived from the bismaleimide resin due to the reaction.

Modification ratio of vinyl group (%)=[(peak area derived from bismaleimide resin before initiation of reaction)−(peak area derived from bismaleimide resin after completion of reaction)]×100/(peak area derived from bismaleimide resin before initiation of reaction)

The modification ratio of vinyl group determined by the equation was 40%.

### [Production of Resin Composition]

### Examples 1 to 5 and Comparative Examples 1 and 2

Components shown in Table 1, toluene, and methyl ethyl ketone were blended in accordance with the blending amounts shown in Table 1, stirred and mixed at 25° C. to prepare resin compositions each having a solid content concentration of about 60 mass %. In Table 1, the unit of the blending amount of each of the components is parts by mass, and in the case of a solution, it means parts by mass in terms of solid content.

### (Production of Resin Film)

The resin composition each obtained as described above was applied to a PET film (manufactured by Teijin Limited. product name: “G2-38”) having a thickness of 38 μm, and then heated and dried at 170° C. for 5 minutes, thereby preparing a resin film in a B-stage state.

(Production of Resin Plate with Double-Sided Copper Foil)

The resin film obtained as described above was peeled off from the PET film and then pulverized, thereby obtaining a resin powder in a B-stage state. A Teflon (registered trademark) sheet having a thickness of 0.5 mm die-cut to a size of 50 mm×35 mm was disposed on a copper foil, and the die-cut portion was charged with a resin powder. Further, a copper foil was disposed on the sheet to obtain a laminate. As the copper foil, a low profile copper foil having a thickness of 18 μm (manufactured by Mitsui Mining & Smelting Co., Ltd., product name: “3EC-M3-VLP-18”) was used, and the copper foil was disposed so that a roughened surface was on the resin powder side. Subsequently, the laminate was heated and press-molded under conditions such as a temperature of 230° C., a pressure of 2.0 MPa, and a time of 120 minutes to cure the resin powder with the resin powder being molded in a resin plate, thereby producing a resin plate with a double-sided copper foil. The thickness of the resin plate portion of the obtained resin plate with a double-sided copper foil was 0.5 mm.

### [Evaluation Method]

Each evaluation was performed in accordance with the following method. The results are shown in Table 1.

### (Method for Evaluating Compatibility)

The resin composition having a solid content concentration of about 60 mass % obtained in each of Examples was observed at a magnification of 50 times with an optical microscope, and the compatibility was evaluated in accordance with the following criteria.
A: Separation was not observed.
B: Separation was slightly observed.
C: Separation wholly occurred.

### (Method for Measuring the Number of Hollows)

The resin plate with a double-sided copper foil obtained in each of Examples was immersed in a copper etchant to remove the copper foils, and the following operations (1) to (4) were performed in turn to perform desmear treatment, thereby producing a resin plate.
(1) The resin plate was immersed in a swelling solution (manufactured by Atotech Japan K.K., product name “Swelling Dip Securiganth P,” an aqueous solution of glycol ethers and sodium hydroxide) at 60° C. for 5 minutes, and then washed with water.
(2) The resin plate was immersed in a roughening liquid (manufactured by Atotech Japan K.K., product name “Concentrate Compact P,” an aqueous solution of 60 g/L of KMnO₄ and 40 g/L of NaOH) at 80° C. for 10 minutes, and then washed with water.
(3) The resin plate was immersed in a neutralization solution (manufactured by Atotech Japan K.K., “Reduction Solution Securiganth P,” an aqueous solution of sulfuric acid) at 40° C. for 5 minutes, and then washed with water.
(4) The resin plate was dried at 80° C. for 10 minutes.

For the surface of the obtained resin plate after desmear treatment, five fields of view were observed with a scanning electron microscope (SEM) (manufactured by Hitachi High-Technologies Corporation, product name “SV-4700”) under conditions such as secondary electron mode, an accelerating voltage of 10 kV, and a magnification of 10,000 times. In a surface SEM image of each of the fields of view, the number of hollows having a size of more than 10 nm on the surface of the resin plate was measured, and an average value thereof was determined. Here, the size of a hollow means the length of the longest straight line among straight lines drawn within the region of the hollow as viewed in plan view of the resin plate.

### (Method for Measuring Relative Permittivity (Dk))

The resin plate with a double-sided copper foil obtained in each Examples was immersed in a 10 mass % solution of ammonium persulfate (manufactured by Mitsubishi Gas Chemical Company, Inc.) that was a copper etchant to remove the copper foils. The obtained resin plate was cut in a size of 2 mm×50 mm, and then dried at 105° C. for 1 hour to obtain a test piece. Subsequently, the relative permittivity (Dk) of the test piece was measured at an atmosphere temperature of 25° C. in a 10 GHz zone in accordance with a cavity resonator perturbation method.

### (Method for Evaluating Laser Processability)

In the resin plate with a double-sided copper foil obtained in each of Examples, a via hole was formed using a CO₂ laser processing machine (VIA MECHLC-2N252/2C (H18 machine), manufactured by Via Mechanics, Ltd.) under conditions of a mask diameter of 1.6 mm, a focus offset value of 0.000, a pulse width of 10 s, a power of 6.60 W, an aperture of 43, and a shot count of 1.

The copper foil around the via hole of the evaluation substrate obtained above was observed with a scanning electron microscope (SEM), and laser processability was evaluated in accordance with the following criteria.
A: Peeling and bulge were not observed in the copper foil around the via hole.
B: Slight peeling or bulge was observed in the copper foil around the via hole.
C: Many occurrences of peeling and bulge were observed in the copper foil around the via hole.

TABLE 1

| | | | | | | | | Comparative | |
|---|---|---|---|---|---|---|---|---|---|
| | | | Example | | | | | Example | |
| | | | 1 | 2 | 3 | 4 | 5 | 1 | 2 |
| Blending | (A) | Maleimide | 34.5 | 34.6 | 34.6 | 34.6 | 34.6 | 39.1 | 22.6 |
| composition | Thermosetting | resin 1 | | | | | | | |
| (part | resin | Maleimide | 11.6 | 11.6 | 11.6 | 11.6 | 11.6 | 13.0 | 7.6 |
| by mass) | | resin 2 | | | | | | | |
| | (B) Inorganic | Inorganic | 12.4 | 12.4 | | | | 20.5 | |
| | filler having | filler B-1 | | | | | | | |
| | true density | Inorganic | | | 12.4 | | | | |
| | of 1,500 | filler B-2 | | | | | | | |
| | kg/m³ or | Inorganic | | | | 12.4 | | | |
| | less | filler B-3 | | | | | | | |
| | | Inorganic | | | | | 12.4 | | |
| | | filler B-4 | | | | | | | |
| | (C) Inorganic | Inorganic | 17.2 | | 17.2 | 17.2 | 17.2 | | 52.9 |
| | filler having | filler C-1 | | | | | | | |
| | true density | Inorganic | | 17.2 | | | | | |
| | of more than | filler C-2 | | | | | | | |
| | 1,500 kg/m³ | | | | | | | | |
| | (D) Diene-based | Modified | 15.4 | 15.4 | 15.4 | 15.4 | 15.4 | 17.4 | 10.0 |
| | polymer | conjugated | | | | | | | |
| | | diene | | | | | | | |
| | | polymer | | | | | | | |
| | (E) Styrene- | SEBS | 3.2 | 3.2 | 3.2 | 3.2 | 3.2 | 3.7 | 2.1 |
| | based | | | | | | | | |
| | thermoplastic | | | | | | | | |
| | resin | | | | | | | | |
| | (F) Flame | Phosphate | 4.6 | 4.6 | 4.6 | 4.6 | 4.6 | 4.8 | 2.8 |
| | retardant | ester | | | | | | | |
| | | compound | | | | | | | |
| | (G) Curing | Organic | 1.2 | 1.2 | 1.2 | 1.2 | 1.2 | 1.4 | 0.8 |
| | accelerator | peroxide | | | | | | | |
| | | Imidazole- | 0.06 | 0.06 | 0.06 | 0.06 | 0.06 | 0.08 | 0.03 |
| | | based curing | | | | | | | |
| | | accelerator | | | | | | | |

| | | | | | | | | |
|---|---|---|---|---|---|---|---|---|
| Evaluation | Compatibility | A | B | B | C | A | B | A |
| result | Number of hollows | 0 | 2.1 | 2.3 | 2.3 | 0 | 0 | 0 |
| | Relative permittivity (Dk) | 2.97 | 2.97 | 3.00 | 2.97 | 3.00 | 2.95 | 3.21 |
| | Laser processability | A | B | B | B | B | C | A |

Details of the components shown in Table 1 are as follows.

### [(A) Thermosetting Resin]

Maleimide resin 1: of the maleimide resin represented by the general formula (A-1), an aromatic bismaleimide resin having an indan ring in which X^{A1} is represented by a divalent organic group represented by the general formula (A-7), number-average molecular weight (Mn): 1,300
Maleimide resin 2: biphenyl aralkyl type maleimide resin (manufactured by Nippon Kayaku Co., Ltd., product name: “MIR-3000”)
   [(B) Inorganic Filler Having True Density of 1,500 kg/m³ or Less]
Inorganic filler B-1: an inorganic filler obtained by surface-treating siloxane particles having a true density of 1,350 kg/m³ and an average particle diameter (D₅₀) of 0.7 μm with vinyl silane
Inorganic filler B-2: an inorganic filler obtained by surface-treating siloxane particles having a true density of 1,350 kg/m³ and an average particle diameter (D₅₀) of 0.7 μm with isocyanate silane
Inorganic filler B-3: an inorganic filler obtained by surface-treating siloxane particles having a true density of 1,350 kg/m³ and an average particle diameter (D₅₀) of 0.7 μm with acryl silane
Inorganic filler B-4: an inorganic filler obtained by surface-treating siloxane particles having a true density of 1,350 kg/m³ and an average particle diameter (D₅₀) of 0.7 μm with aminophenyl silane
   [(C) Inorganic Filler Having True Density of More than 1,500 kg/m³]
Inorganic filler C-1: an inorganic filler obtained by surface-treating spherical molten silica having a true density of 2,200 kg/m³ and an average particle diameter (D₅₀) of 0.5 μm with aminophenyl silane
Inorganic filler C-2: an inorganic filler obtained by surface-treating spherical molten silica having a true density of 2,200 kg/m³ and an average particle diameter (D₅₀) of 0.5 μm with vinyl silane

### [(D) Diene-Based Polymer]

Modified conjugated diene polymer: the modified conjugated diene polymer obtained in Production Example 1

### [(E) Styrene-Based Thermoplastic Resin]

SEBS: manufactured by Kraton Polymer Japan Ltd., product name “KRATON (registered trademark) MD1653MO,” melt flow rate: 5.0 g/10 min, styrene content: 30 mass %, hydrogenation ratio: 100%

### [(F) Flame Retardant]

Phosphate ester compound: 4,4′-biphenol-bis(di-2,6-xylenyl phosphate)

### [(G) Curing Accelerator]

Organic peroxide: α,α′-bis(t-butylperoxy)diisopropylbenzene
Imidazole-based curing accelerator: isocyanate-masked imidazole (an addition reaction product of a hexamethylene diisocyanate resin and 2-ethyl-4-methylimidazole) (manufactured by DKS Co., Ltd., product name “G-8009L”)

As seen from the results shown in Table 1, the resin compositions of Examples 1 to 5 of the present embodiment had both excellent relative permittivity (Dk) and excellent laser processability. Meanwhile, the resin composition containing no component (C) of Comparative Example 1 had low laser processability, and the resin composition containing no component (B) of Comparative Example 2 had low relative permittivity (Dk).

1. A resin composition comprising:
(A) a thermosetting resin;
(B) an inorganic filler having a true density of 1,500 kg/m³ or less; and
(C) an inorganic filler having a true density of more than 1,500 kg/m³.

2. The resin composition according to claim 1, wherein the component (B) is a particle having a siloxane bond.

3. The resin composition according to claim 1, wherein a content of the component (B) is 1 to 30 mass % with respect to a total amount (100 mass %) of a solid content of the resin composition.

4. The resin composition according to claim 1, wherein the component (C) is silica.

5. The resin composition according to claim 1, wherein a content of the component (C) is 2 to 40 mass % with respect to a total amount (100 mass %) of a solid content of the resin composition.

6. The resin composition according to claim 1, wherein a difference between a true density of the component (B) and a true density of the component (C) [true density of component (C)−true density of component (B)] is 400 to 1,000 kg/m³.

7. The resin composition according to claim 1, wherein the component (A) is one or more selected from the group consisting of a maleimide compound having one or more N-substituted maleimide groups and a derivative of the maleimide resin.

8. A prepreg comprising:
the resin composition according to claim 1 or a semi-cured product of the resin composition.

9. A layered sheet comprising:
a cured product of the resin composition according to claim 1; and
a metal foil.

10. A resin film comprising:
the resin composition according to claim 1 or a semi-cured product of the resin composition.

11. A printed circuit board comprising:
a cured product of the resin composition according to claim 1.

12. A semiconductor package comprising:
the printed circuit board according to claim 11; and a semiconductor element.
